(19) United States
(12) Patent Application Publication
(10) Pub. No.: US 2007/0090431 A1
(43) Pub. Date: Apr. 26, 2007

(54) Device layout for reducing device upset due to single event effects

(75) Inventor: David O. Erstad, Minnetonka, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/257,322

(22) Filed: Oct. 24, 2005

(51) Int. Cl. H01L 27/108

(52) U.S. Cl. 257/297

(57) ABSTRACT

A device layout for reducing device upset due to single event effects is described. A transistor is formed on a substrate. The transistor has a source, a drain, and a gate. The drain and/or the source are formed such that the drain and/or the source have a low impedance contact region, and a high impedance region between the gate and the contact region. The low impedance contact region may be formed by using a silicide over a portion of the drain and/or the source. As another example, the low impedance contact region may be formed by using multiple contacts aligned to be substantially parallel to the gate. The effect of combining the low impedance contact region and the high impedance region is that when an energetic particle strikes a device, effective resistance of the drain and/or the source increases, which reduces device upset to single event effects while minimizing the impact to device performance.

### FIELD

The present invention relates generally to device layout, and more particularly, relates to a device layout that reduces device upset due to single event effects.

### BACKGROUND

Single Event Effects (SEE) are disturbances in an active semiconductor device caused by a single energetic particle. As semiconductor devices become smaller and smaller, transistor threshold voltages also decrease. These lower thresholds reduce the ionizing field charge per node needed to cause errors. As a result, the semiconductor devices become more and more susceptible to transient upsets.

One type of SEE is a single event upset (SEU). SEU is a radiation-induced error in a semiconductor device caused when charged particles lose energy by ionizing the medium through which they pass, leaving behind a wake of electron-hole pairs. The electron-hole pairs form a parasitic conduction path, which can cause a false transition on a node. The false transition, or glitch, can propagate through the semiconductor device and may ultimately result in the disturbance of a node containing state information, such as an output of a latch, register, or gate.

One type of SEU is a single event transient (SET). SETs occur when a particle strikes a sensitive node within a combinational logic circuit. A voltage disturbance produced at that node may propagate through the logic. As a result of the SET, the combinational logic circuit may provide an erroneous output, which could impact the proper operation of a system that includes the circuit.

Typically, SEUs are caused by ionizing radiation components, such as neutrons, protons, and heavy ions. The ionizing radiation components are abundant in space and also at commercial flight altitudes. Additionally, SEUs can be caused by alpha particles from the decay of trace concentrations of uranium and thorium present in some integrated circuit packaging. As another example, SEUs may be caused by detonating nuclear weapons. When a nuclear weapon is detonated, intense fluxes of gamma rays, x-rays, and other high energy particles are created.

Some semiconductor devices are designed to operate in conditions that expose the devices to energetic particles. These devices are typically modified to be hardened against SEE. For example, resistors have been added to semiconductor devices to provide SEU hardness. A resistor slows the change of an output node during an SEU hit, which may prevent the output node from making a false transition. However, the resistor also slows the overall function of the device, which is undesirable. Additionally, the resistor occupies space, which may impact the packing density or “scaling” of the device.

Therefore, it would be beneficial to have a device layout that reduces device upset due to SEE, but does not reduce the speed and/or increase the area of the device.

### SUMMARY

A device layout that reduces device upset due to single event effects is described. A transistor is formed on a substrate. The transistor has a source, a drain, and a gate. A contact region is located on at least one of the source and the drain. At least one contact is formed in the contact region. A second region is located between the contact region and the gate having an impedance greater than an impedance of the contact region. Effective resistance in the second region increases when an energetic particle strikes the transistor.

In one example, a silicide overlays the contact region and is restricted from overlaying the second region. This results in the impedance of the second region being greater than the impedance of the contact region.

In another example, a plurality of contacts is located in the contact region causing the impedance of the contact region to be less than the impedance of the second region. The plurality of contacts is aligned to be substantially parallel with the gate. Additionally, the plurality of contacts is spaced apart at a regular interval. A silicide may be restricted from overlaying the contact region and the second region. Alternatively, a silicide is limited to overlaying a portion of the contact region located substantially under the plurality of contacts formed in the contact region.

In this example, the device layout may further include a lightly doped region located in a region of the substrate between the plurality of contacts and the gate. A spacer may be located adjacent to the gate. The spacer extends the lightly doped region.

A device layout for reducing device upset due to single event effects may include a substrate, a transistor having a source, a drain, and a gate formed on the substrate, a contact region in at least one of the source and the drain, and a second region between the contact region and the gate. A silicide overlays the contact region, but is restricted from overlaying the second region so that the second region has an impedance greater than an impedance of the contact region.

A device layout for reducing device upset due to single event effects may include a substrate, a transistor having a source, a drain, and a gate formed on the substrate, a contact region in at least one of the source and the drain, and a second region between the contact region and the gate. A plurality of contacts is located in the contact region. The plurality of contacts causes the contact region to have an impedance that is less than an impedance of the second region.

In this example, the plurality of contacts is aligned to be substantially parallel with the gate. Additionally, the plurality of contacts may be spaced apart at a regular interval. A silicide may be restricted from overlaying the contact region and the second region. Alternatively, a silicide is limited to overlaying a portion of the contact region located substantially under the plurality of contacts formed in the contact region.

The device layout may further include a lightly doped region located in a region of the substrate between the plurality of contacts and the gate. A spacer may be located adjacent to the gate. The spacer extends the lightly doped region.

Beneficially, this device layout provides a variable effective resistance with little or no area penalty for increasing effective resistance during an SEE. As a result, both new and existing circuit designs may be hardened against the effects of SEE using the described device layouts. Moreover, the layouts minimize the impact to device performance during normal operation.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a top view of a typical transistor;

FIG. 2 is a side view of the typical transistor depicted in FIG. 1;

FIG. 3 is a top view of a transistor, according to an example;

FIG. 4 is a side view of the transistor depicted in FIG. 3, according to an example;

FIG. 5 is a top view of a transistor, according to another example;

FIG. 6 is a side view of the transistor depicted in FIG. 5, according to an example;

FIG. 7 is a side view of the transistor depicted in FIG. 5, according to another example;

FIG. 8 is a top view of a transistor showing current flow during normal operating conditions;

FIG. 9 is a top view of a transistor showing current flow during an SEU hit to a gate;

FIG. 10 is a top view of a transistor showing a spreading resistance effect due to an SEU hit to a gate, according to an example; and

FIG. 11 is a top view of a transistor showing a spreading resistance effect due to an SEU hit to a gate, according to another example.

### DETAILED DESCRIPTION

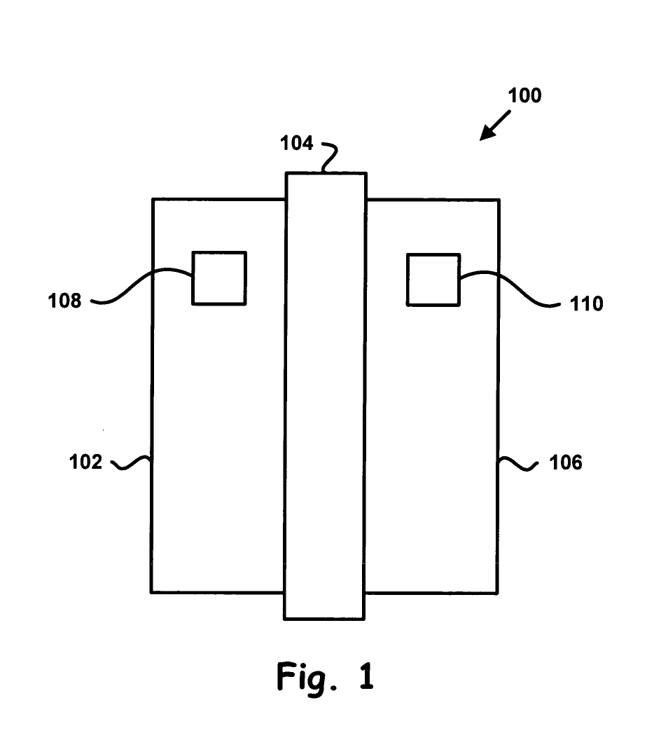

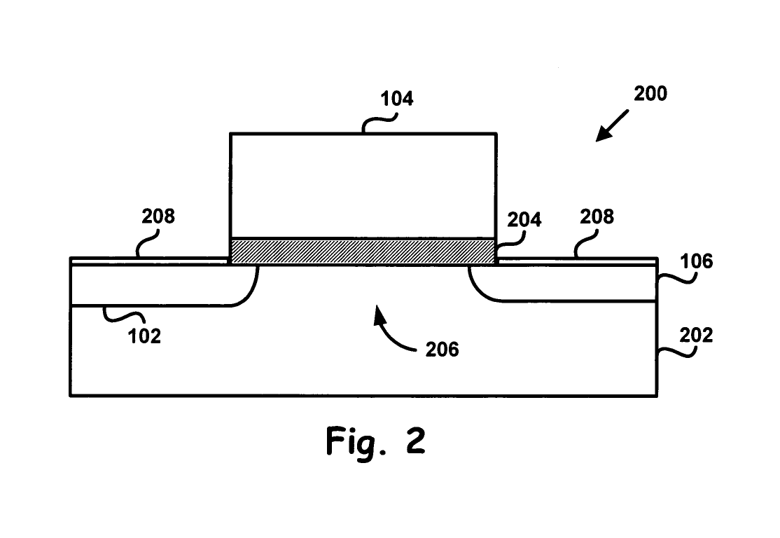

FIG. 1 is a top view of a typical transistor 100, such as a metal-oxide-semiconductor (MOS) transistor. The transistor 100 is formed on a substrate 202 (depicted in FIG. 2). The transistor 100 includes a source 102, a gate 104, and a drain 106. A channel 206 (depicted in FIG. 2) is located under the gate 104 between the source 102 and the drain 106.

The substrate 202 has an associated dopant type. The source 102 and the drain 106 are formed by doping the substrate 202 with a different dopant type than the dopant type used to dope the substrate 202. An example P-type dopant is boron. An example N-type dopant is phosphorous. For example, if the substrate 202 is doped with a p-type dopant, the source 102 and the drain 106 are doped with an n-type dopant forming an NMOS transistor 100. As another example, if the substrate 202 is doped with an n-type dopant, the source 102 and the drain 106 are doped with a p-type dopant forming a PMOS transistor 100.

The source 102 and the drain 106 are typically heavily doped, except for a lightly doped drain (LDD) region near the gate 104. The LDD region may reduce the electric field in the channel region 206, which may reduce hot-carrier effects. Hot-carrier effects include charge injection, substrate current, and electron injection into a gate oxide layer 204 (depicted in FIG. 2) formed between the gate 104 and the substrate 202.

Current flows between the source 102 and the drain 106 depending on the charge applied to the gate 104. Contacts are formed on the source 102, the gate 104, and the drain 106 so that the transistor 100 can be connected to other devices in a circuit. As depicted in FIG. 1, the source 102 includes a contact 108 and the drain 106 includes a contact 110. Typically, the source 102 and drain 106 have a single contact. However, sometimes two contacts are located on the source 102 and/or the drain 106 for redundancy and/or yield. When two contacts are located on either the source 102 and/or the drain 106, the contacts are typically located close to each other to minimize the length of the wires and/or traces.

Typically, a silicide 208 (depicted in FIG. 2) is formed over the source 102 and the drain 106 to reduce source/drain resistance, improving the performance of the transistor 100. A metal material, such as titanium, tungsten, cobalt, or nickel, may be deposited on the substrate 202 to overlay the source 102 and the drain 106. After the metal is deposited on the substrate 202, thermal processing may be performed to form the silicide 208. Depending on the type of metal used, the silicide 208 may be composed of titanium silicide, tungsten silicide, cobalt silicide, and so on.

The contacts 108, 110 are formed on the silicide 208. The contacts 108, 110 may be composed of a conducting metal. For example, the metal may be a metal film composed of aluminum. However, other metals may also be suitable for forming the contacts 108, 110. The metal film may be deposited on the silicide 208 using typical metallization processes. For example, a contact hole may be etched into the silicide 208. Following contact masking, a thin layer of the conducting metal may be deposited into the contact hole using vacuum evaporation, sputtering, or any other appropriate deposition technique. The contacts 108, 110 may then undergo alloying, a heat-treatment process that is used to ensure a good electrical contact between the contacts 108, 110 and the substrate 202.

FIG. 2 is a side view 200 of the transistor 100 depicted in FIG. 1. In FIG. 2, the silicide 208 overlaying the source 102 and the drain 106 is depicted. Additionally, the substrate 202 is visible. The substrate 202 may be bulk silicon, silicon-on-insulator, or any other type of suitable substrate. The channel 206 is located under the gate 104 and substantially between the source 102 and the drain 106. The gate oxide layer 204 is formed on the substrate 202 prior to forming the gate 104 on the gate oxide layer 204.

It would be beneficial to modify the device layout depicted in FIGS. 1-2 to reduce upset due to single event effects. By modifying the drain 106 and/or the source 102 to include a low impedance contact region, and a high impedance region between the gate 104 and the low impedance contact region, upsets due to single event effects may be reduced. The low impedance contact region has an impedance that is less than the impedance of the high impedance region. As described below, the low impedance contact region and the high impedance region may be formed in a variety of ways.

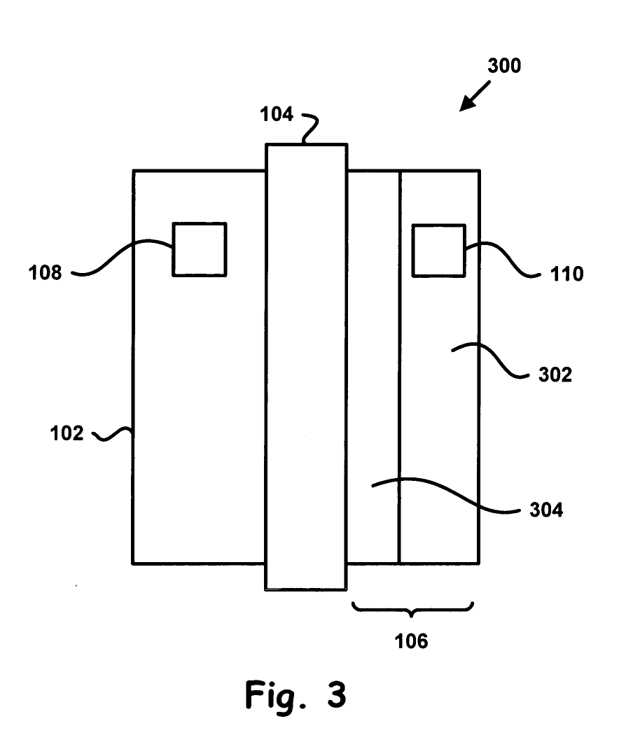

FIG. 3 is a top view of a transistor 300. In this example, a high impedance region 304 is formed by preventing the formation of a silicide over part of the drain 106 and/or source 102 of the transistor 300. A contact region 302 of the drain 106 and/or source 104 includes a layer of silicide 208, which reduces the impedance in the contact region 302. While FIG. 3 depicts the drain 106 having high and low impedance contact regions, it is understood that similar regions may be additionally or alternatively formed on the source 102.

The transistor 300 may be formed on bulk silicon, silicon-on-insulator (SOI), or any other type of substrate. Additionally, if the transistor 300 is formed on an SOI substrate, the SOI substrate may be fully or partially depleted. Moreover, a body of the SOI substrate may be floating or tied.

The transistor 300 includes the source 102, the gate 104, and the drain 106. The source 102 includes the contact 108, while the drain 106 includes the contact 110. In contrast to the typical transistor depicted in FIG. 1, the drain 106 includes the low impedance contact region 302 and the high impedance region 304. The drain contact 110 is formed in the low impedance contact region 302. The high impedance region 304 is located between the low impedance contact region 302 and the gate 104.

The high impedance region 304 is formed to have an impedance greater than the impedance of the low impedance contact region 302. To create a higher impedance in the high impedance region 304, the silicide 208 may not be deposited in the high impedance region 304. As described above, the silicide 208 reduces resistance. Because the silicide is deposited in the low impedance contact region 302 and not in the high impedance region 304, the high impedance region 304 has an impedance that is greater than the impedance of the low impedance contact region 302.

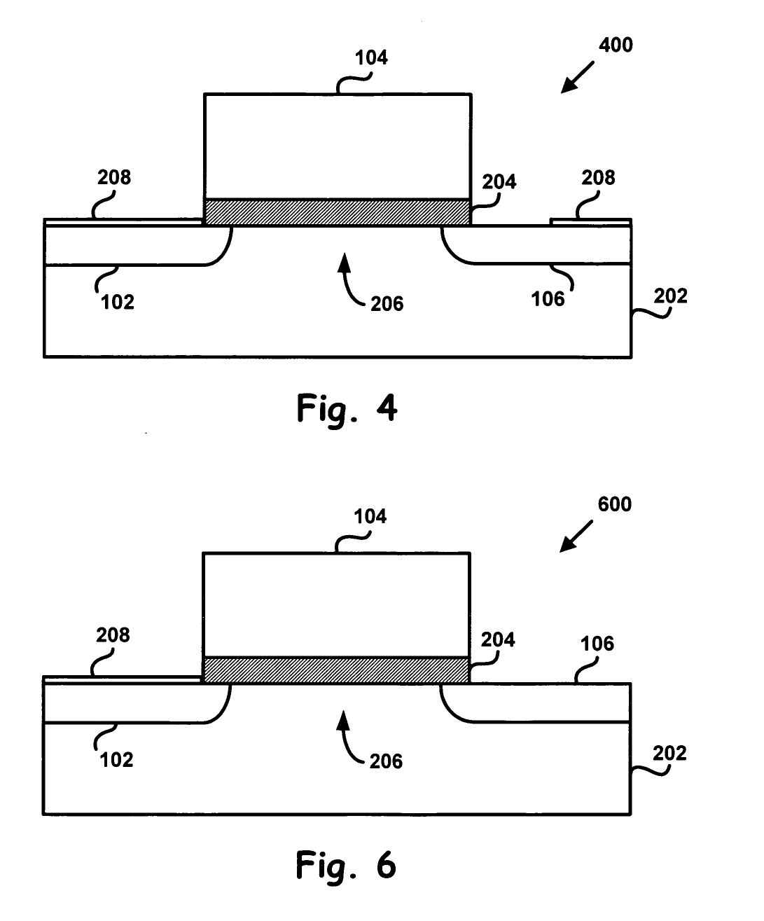

FIG. 4 is a side view 400 of the transistor 300 depicted in FIG. 3. In FIG. 4, the silicide 208 can be seen. The region in which the silicide 208 overlays the drain 106 is the low impedance contact region 302, while the region in which the silicide 208 does not overlay the drain 106 is the high impedance region 304.

By constructing the transistor 300 with the low impedance contact region 302 and the high impedance region 304 between the contact region 302 and the gate 104, when an energetic particle strikes the device, effective resistance of the drain 106 increases. By increasing the effective resistance of the drain 106, device upset due to single event effects is reduced, while minimizing the impact to device performance during normal operation.

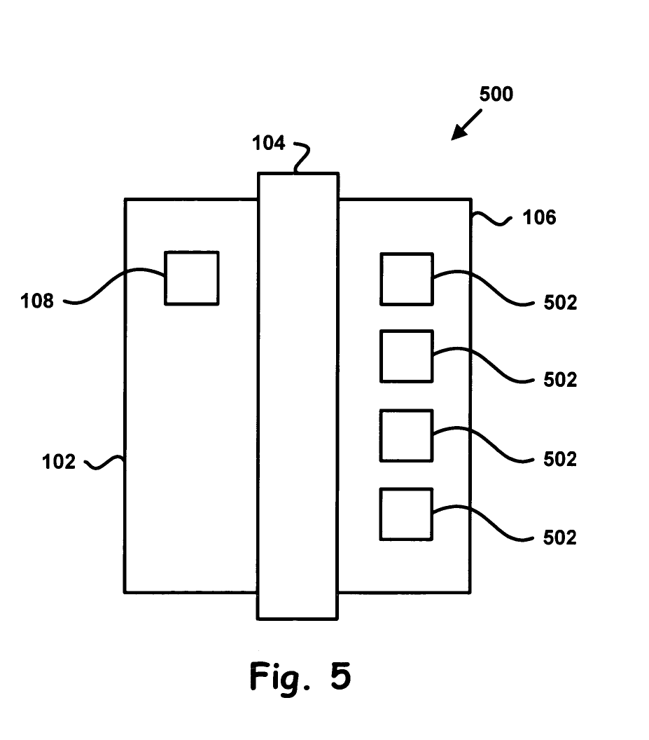

Other methods for forming a low impedance contact region and high impedance region in the drain 106 and/or source 102 may also be used. For example, another transistor layout is depicted in FIG. 5 for forming a low impedance contact region, and a high impedance region between the gate 104 and the low impedance contact region. In this example, the silicide 208 is not deposited on the drain 106. The low impedance contact region is formed by depositing multiple drain contacts 502 as described below. While this example is also described with respect to the drain, it is understood that this layout may also be implemented on the source 102, or on both the drain 106 and the source 102.

FIG. 5 depicts a top view of a transistor 500. The transistor 500 may be formed on bulk silicon, SOI, or any other type of substrate. Additionally, if the transistor 500 is formed on an SOI substrate, the SOI substrate may be fully or partially depleted. Moreover, a body of the SOI substrate may be floating or tied.

The transistor 500 includes the source 102, the gate 104, and the drain 106. The source 102 includes the contact 108. However, in contrast to the transistor 100, the drain 106 has multiple contacts 502. FIG. 5 depicts four drain contacts 502; however, a different plurality of drain contacts 502 may be used. The number of drain contacts 502 may depend on the size of the transistor 500. For example, five drain contacts 502 may be used for a six micron transistor.

The drain contacts 502 may be aligned to be substantially parallel with the gate 104. However, perfect alignment is unnecessary. For example, the drain contacts 502 may form a line located a distance of approximately 0.3 microns from the gate 104. However, the distance from the gate 104 to provide adequate protection against SEE may vary widely based on the type of technology used.

The drain contacts 502 may be spaced apart at a regular interval to distribute effective resistance along the line of drain contacts 502. For example, the drain contacts 502 may be spaced approximately 1 micron apart. Other spacing distances between the drain contacts 502 may also be appropriate for protecting against SEE. Additionally, the drain contacts 502 may be separated by adding extra space than is typically required by normal layout rules.

Depending on the technology, multiple contacts may be formed on the drain 106 and/or the source 102 without increasing the area of the transistor 500. Moreover, additional contacts may be added to existing layouts. As a result, both new and existing circuit designs may be hardened against the effects of SEE. This device layout approach also provides a smaller resistance during normal operation than during an SEU hit and does not interfere with the restoring current of the transistor 500.

FIG. 6 is a side view 600 of the transistor 500 depicted in FIG. 5. In this example, the transistor 500 is fabricated so that the silicide 208 overlays the source 102, but not the drain 106 of the transistor 500. Alternatively, the silicide 208 may overlay the drain 106 only in the region located under the drain contacts 502. Eliminating or reducing the silicide 208 on the drain 106 may increase the effective resistance of the drain 106 during an SEE.

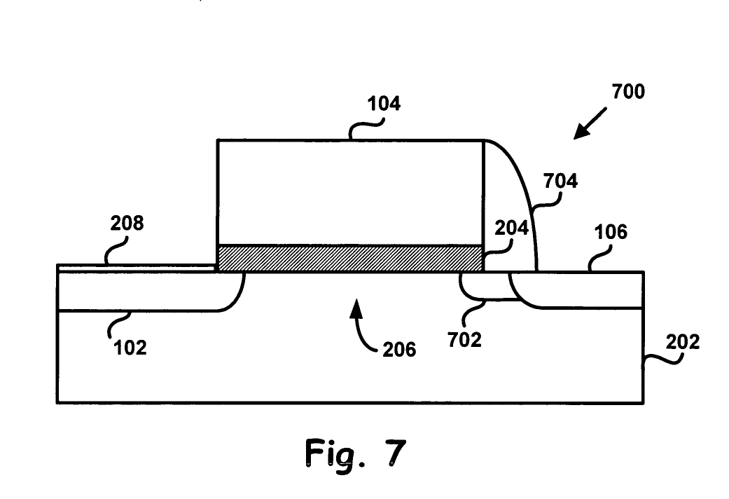

FIG. 7 is another side view 700 of the transistor 500 depicted in FIG. 5. In this example, an LDD implant 702 is performed in the region of the substrate 202 between the drain contacts 502 and the gate 104. If the transistor 500 includes the LDD implant 702, a spacer 704 may also be used to extend the LDD region. The spacer 704 may be formed on a lateral edge of the gate 104 by depositing an insulating material and etching the material to form the spacer 704. For example, the spacer 704 may be composed of silicon nitride. Other materials and fabrication processes may also be used for forming the spacer 704.

Also in this example, the transistor 500 is fabricated so that the silicide 208 overlays the source 102, but not the drain 106 of the transistor 500. Alternatively, the silicide 208 may overlay the drain 106 only in the region located under the drain contacts 502.

As yet another device layout example, additional contacts may be added to the source 102 in addition to or instead of the multiple drain contacts 502 on the drain 106. Additionally, the silicide 208 may be eliminated from the source 102 or limited to being located only under the additional contacts added to the source 102. Additionally, an LDD implant may be performed in the area between the additional contacts added to the source 102 and the gate 104. If an LDD implant is located between the additional contacts added to the source 102 and the gate 104, a spacer may be used to extend this LDD region.

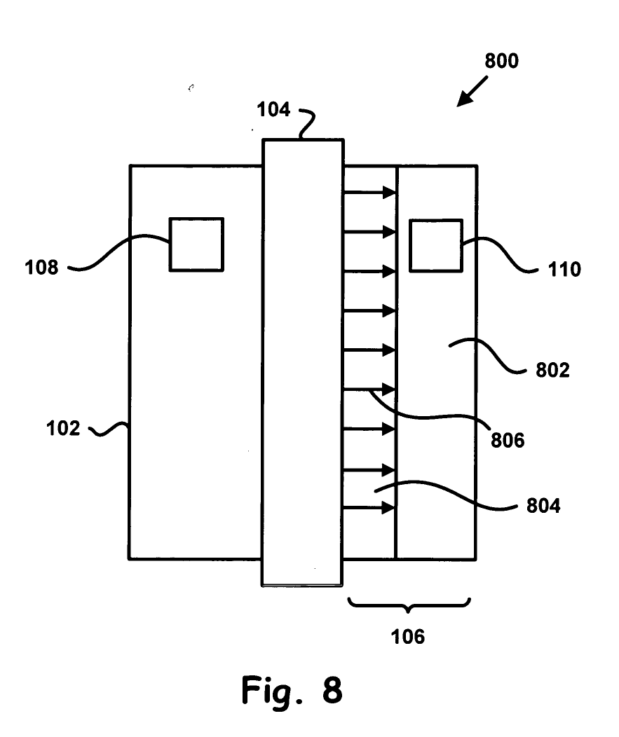

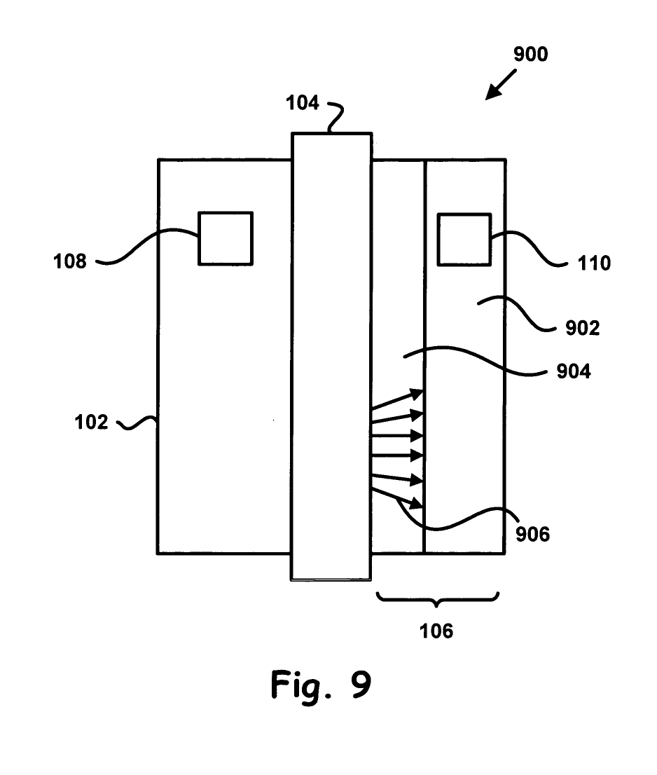

FIG. 8 is a top view of a transistor showing current flow during normal operating conditions. As shown in FIG. 8, current flows 806 from the gate 104 to the low impedance contact region 802 in a roughly homogenous horizontal pattern. However, when an SEU hit to the gate 104 occurs, current flow 906 radiates from the point of the SEU hit as depicted in FIG. 9. The SEU hit typically occupies a small portion of a width of the transistor 900. For example, the SEU hit may occupy one micron of width.

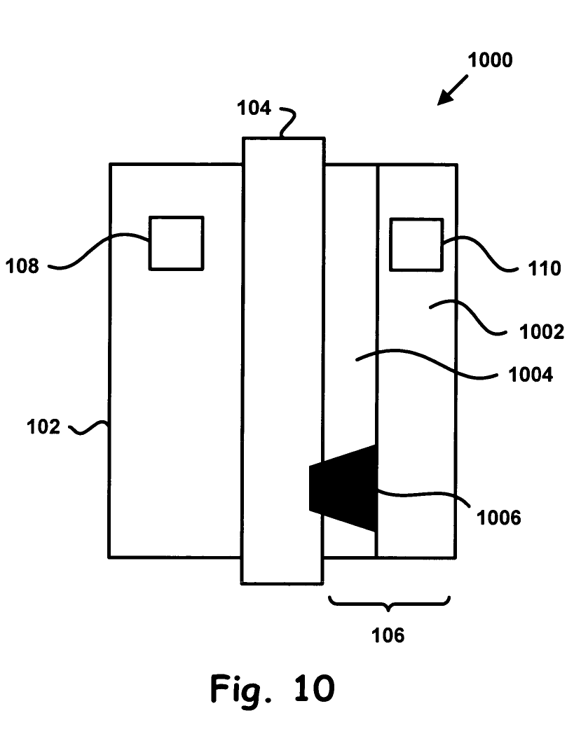

FIG. 10 is a top view of a transistor 1000 showing a spreading resistance effect due to the SEU hit to the gate 104. In this example, the transistor 1000 is formed by providing the silicide 208 in the low impedance contact region 1002, and not the high impedance region 1004. A spreading resistance 1006 is formed from the gate 104 towards the low impedance contact region 1002. The effective resistance increases during a SEE. Current generated by the SEU hit is limited by the spreading resistance 1006, which may limit the impact of the SEU hit on the overall operation of the transistor 1000.

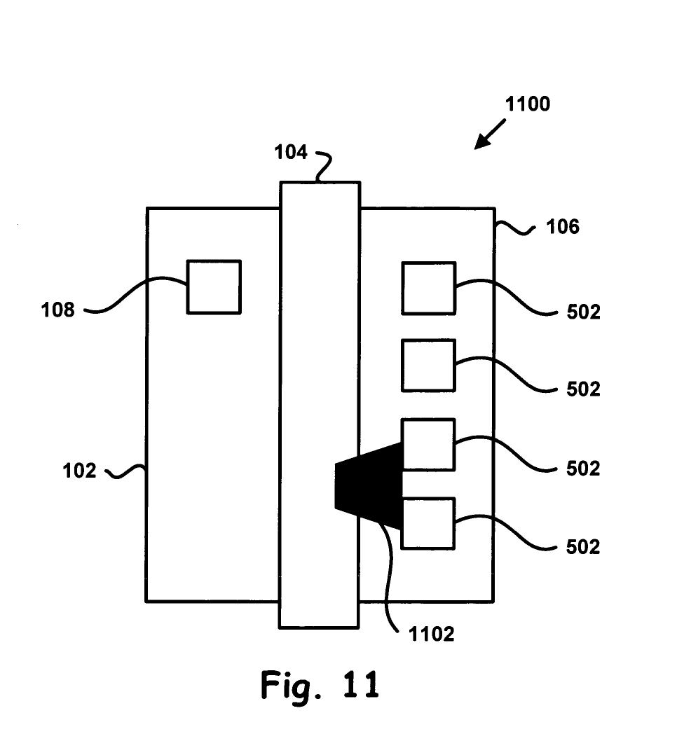

FIG. 11 is a top view of another transistor 1100 showing the spreading resistance effect due to the SEU hit to the gate 104. In this example, the transistor 1100 is formed by not depositing the silicide 208 on the drain 106 and depositing multiple drain contacts in the contact region. A spreading resistance 1102 is formed from the gate 104 towards the drain contacts 502. The effective resistance increases during a SEE. Current generated by the SEU hit is limited by the spreading resistance 1102, which may limit the impact of the SEU hit on the overall operation of the transistor 1100.

A simulation was performed on a device similar to the transistor 500 in which no silicide is deposited on the drain and multiple contacts are used to form a low impedance contact region. In the simulation, the substrate 202 was a silicon-on-insulator substrate and the device was a 6.8 micron transistor with a P drain sheet rho of 5K and an N drain sheet rho of 2K. The SEU hit was modeled as being 1 micron wide. The spreading resistance 1102 from the SEU hit was modeled as a 1 micron trapezoid with 45 degree sides. With a single drain contact 110 and a normally silicided drain, approximately 1E-9 errors/bit-day occurred in a geosynchronous radiation environment. However, when multiple drain contacts 502 were used, the number of errors that occurred reduced to approximately 6E-13 errors/bit-day. The simulation showed a five-fold increase in resistance between normal resistance and SEU resistance for this 6.8 micron transistor.

By modifying the drain and/or the source to include a low impedance contact region, and a high impedance region between the gate and the low impedance contact region, upsets due to single event effects may be reduced. The effective resistance is smaller during normal operation than during an SEE event, thus the layouts described herein provide SEE protection with little or no area penalty relative to traditional methods that incorporate the same level of protection using a fixed resistance. Moreover, the layouts minimize the impact to device performance during normal operation.

It should be understood that the illustrated embodiments are examples only and should not be taken as limiting the scope of the present invention. For example, a MOS transistor was used to describe the invention. However, the invention may be used with other transistor types and/or other device types. The claims should not be read as limited to the described order or elements unless stated to that effect. Therefore, all embodiments that come within the scope and spirit of the following claims and equivalents thereto are claimed as the invention.

I claim:

1. A device layout for reducing device upset due to single event effects, comprising in combination:
a substrate;
a transistor formed on the substrate, wherein the transistor has a source, a drain, and a gate;
a contact region in at least one of the source and the drain, wherein at least one contact is formed in the contact region; and
a second region between the contact region and the gate having an impedance greater than an impedance of the contact region, wherein effective resistance in the second region increases when an energetic particle strikes the transistor.

2. The device layout of claim 1, wherein a silicide overlays the contact region and is restricted from overlaying the second region so that the impedance of the second region is greater than the impedance of the contact region.

3. The device layout of claim 1, wherein a plurality of contacts is located in the contact region causing the impedance of the contact region to be less than the impedance of the second region.

4. The device layout of claim 3, wherein the plurality of contacts is aligned to be substantially parallel with the gate.

5. The device layout of claim 4, wherein the plurality of contacts is spaced apart at a regular interval.

6. The device layout of claim 3, wherein a silicide is restricted from overlaying the contact region and the second region.

7. The device layout of claim 3, wherein a silicide is limited to overlaying a portion of the contact region located substantially under the plurality of contacts formed in the contact region.

8. The device layout of claim 3, further comprising a lightly doped region located in a region of the substrate between the plurality of contacts and the gate.

9. The device layout of claim 8, further comprising a spacer located adjacent to the gate, wherein the spacer extends the lightly doped region.

10. A device layout for reducing device upset due to single event effects, comprising in combination:
a substrate;
a transistor formed on the substrate, wherein the transistor has a source, a drain, and a gate;
a contact region in at least one of the source and the drain, wherein a silicide overlays the contact region; and
a second region between the contact region and the gate, wherein the silicide is restricted from overlaying the second region so that the second region has an impedance greater than an impedance of the contact region.

11. A device layout for reducing device upset due to single event effects, comprising in combination:
a substrate;
a transistor formed on the substrate, wherein the transistor has a source, a drain, and a gate;
a contact region in at least one of the source and the drain, wherein a plurality of contacts is located in the contact region; and
a second region between the contact region and the gate, wherein the plurality of contacts causes the contact region to have an impedance that is less than an impedance of the second region.

12. The device layout of claim 11, wherein the plurality of contacts is aligned to be substantially parallel with the gate.

13. The device layout of claim 12, wherein the plurality of contacts is spaced apart at a regular interval.

14. The device layout of claim 11, wherein a silicide is restricted from overlaying the contact region and the second region.

15. The device layout of claim 11, wherein a silicide is limited to overlaying a portion of the contact region located substantially under the plurality of contacts formed in the contact region.

16. The device layout of claim 11, further comprising a lightly doped region located in a region of the substrate between the plurality of contacts and the gate.

17. The device layout of claim 16, further comprising a spacer located adjacent to the gate, wherein the spacer extends the lightly doped region.
